(19) United States
(12) Patent Application Publication
(10) Pub. No.: US 2008/0001246 A1
(43) Pub. Date: Jan. 3, 2008

(54) SINGLE PACKAGE DETECTOR AND DIGITAL CONVERTER INTEGRATION

(76) Inventors: Dipak Sengupta, Boxboro, MA (US); Michael Zylinski, Haverhill, MA (US)

Correspondence Address: GAUTHIER & CONNORS, LLP, 225 FRANKLIN STREET, SUITE 2300, BOSTON, MA, 02110, US

(21) Appl. No.: 11/753,032

(22) Filed: May 24, 2007

Related U.S. Application Data
(60) Provisional application No. 60/808,194, filed on May 24, 2006.

(51) Int. Cl. H01L 31/00; H01L 21/00

(52) U.S. Cl. 257/459; 438/59; 257/E21.001; 257/E23.001

(57) ABSTRACT

An integrated package arrangement for an electronic system includes a photodetector module for incorporating a photodetector for use by the electronic system. An analog to digital converter (ADC) module is coupled to the photodetector module. The ADC module includes a plurality of ADC dies for use by an ADC of the electronic system.

### PRIORITY INFORMATION

This application claims priority from provisional application Ser. No. 60/808,194 filed May 24, 2006, which is incorporated herein by reference in its entirety.

### BACKGROUND OF THE INVENTION

The invention is related generally to a wide array of sensor applications where the sensor needs to be in close proximity to the data acquisition electronics to minimize interconnect complexity, improve electrical performance and reduce system size and cost.

This invention describes a specific application in the field of, for example, continuous time (CT) scanners, and in particular to a single package detector and digital converter integration, which can be used in a CT scanner.

The CT scanner market is undergoing a revolution in system integration to enable faster machines in the medical market. These machines are capable of providing clear 3-D view of human body at a high patient throughput rate. At the core of these machines, design innovations are required to enable more efficient system performance, space savings and cost.

Currently, the detectors and the associated converter electronics used in CT scanner are located in separate locations, which make it difficult to gain the performance and higher throughput advantages. There is a need in the art to combine the detector and associated converter electronics in a single package for effectively increase performance and higher throughput advantages.

### SUMMARY OF THE INVENTION

According to one aspect of the invention, there is provided an integrated package arrangement for an electronic system. The integrated package arrangement includes a An analog to digital converter (ADC) module is coupled to the photodetector module. The ADC module includes a plurality of ADC dies for use by an ADC of the electronic system.

According to another aspect of the invention, there is provided a method of integrating a photodetector and an analog digital converter (ADC) of an electronic system. The method includes providing photodetector module for incorporating a photodetector for use by the electronic system. Also, the method includes coupling an analog to digital converter (ADC) module to the photodetector module. The ADC module includes a plurality of ADC dies for use by an ADC of the electronic system.

According to another aspect of the invention, there is provided a method of forming an integrated package arrangement for an electronic system. The method includes a forming photodetector module for incorporating a photodetector for use by the electronic system. Also, the method includes forming an analog to digital converter (ADC) module being coupled to the photodetector module. The ADC module includes a plurality of ADC dies for use by an ADC of the electronic system.

### BRIEF DESCRIPTION OF THE DRAWINGS

FIG. 1 is a schematic diagram illustrating a package arrangement integrating a photodetector and an analog to digital converter (ADC) dies of a CT scanner;

FIG. 2 is a schematic diagram illustrating a package arrangement having substantially similar components as the package element of FIG. 1 except a photodetector is removed;

FIG. 3 is a schematic diagram illustrating a package arrangement having no laminate substrate; and

FIG. 4 is schematic diagram illustrating a package arrangement having ADC dies mounted on the top side of a laminate.

### DETAILED DESCRIPTION OF THE INVENTION

The invention provides a solution enabling efficient usage of system space which in turn helps to provide enhanced system detection capability, more patient scanning per unit time and overall lower system cost for electronic systems, such as a CT scanner. The invention also aids in designing flexible, scaleable detector modules which can be used for varying electronic system configurations, such as other medical electronics, digital cameras, IR imagers, laboratory instruments, photodiodes, or the like.

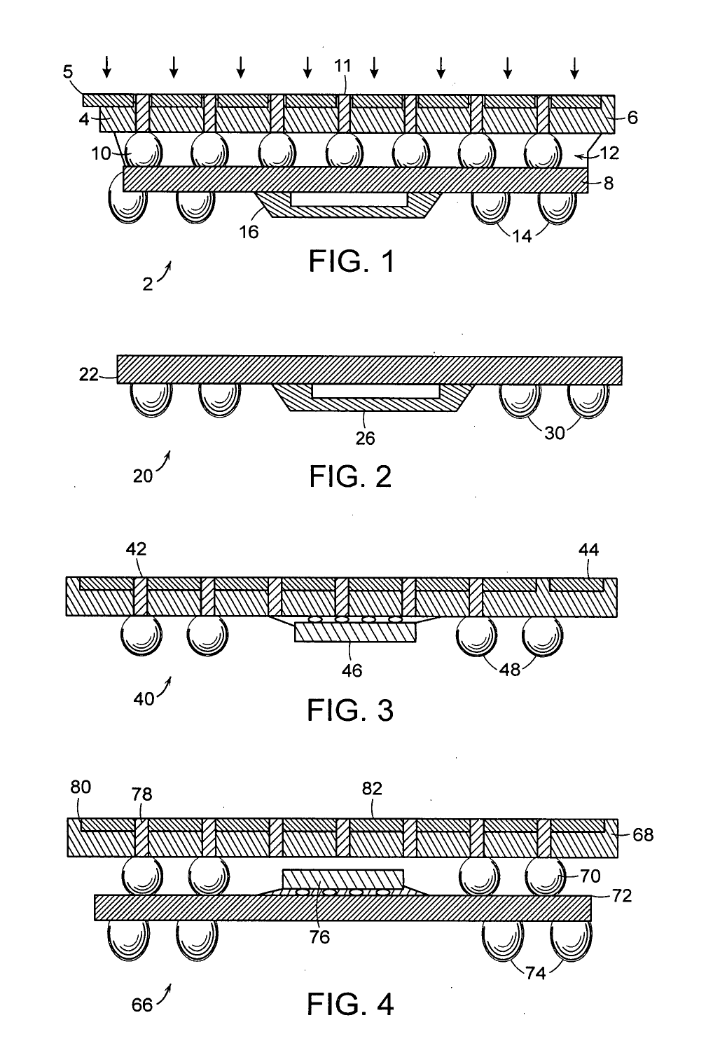

FIG. 1 shows a package arrangement 2 integrating a photodetector 11 and an analog to digital converter (ADC) dies 16 of a CT scanner. The package arrangement 2 includes a photodetector 11 having solder balls 10 for coupling on a laminate substrate 8 with multiple ADC dies 16. The photodetector 11 includes a photodiode junction 5 on the top scintillator side and photodetector dies 6. Vias 4 are used for coupling the photodiode junctions 5 to solder balls 10. The solder balls 10 are encapsulated using organic material on the laminate substrate 8. An underfill 12 encapsulates the solder balls 10 and the region between the photodetector dies 6 and laminate substrate 8. This allows for overhang of the photodetector dies 6 to meet at least a 160 μm spacing used in other customer boards. The photodetectors dies 6 are designed to be longer then the laminate substrate 8 and the underfill 12 includes a region that is slightly larger lengthwise then the laminate substrate 12. This permits overhanging of the photodector dies 6.

The ADC dies 16 are plastic molded on the opposite side of the laminate substrate 8. On the same side, solder balls 14 are provided so as to allow a PC board to be coupled to the package arrangement 2. In other embodiments, ceramic interposers can be provided in place of the laminate substrate 8. Also, multiple ADC dies can be provided for one BGA package.

The package arrangement 2 can also be applied in other electronic systems such as medical electronics, digital cameras, IR imagers, laboratory instruments, photodiodes, or the like.

However, the invention permits other types of photodetector modules to be used beside the one described in FIG. 1. FIG. 2 shows a package arrangement 20 having substantially similar components as the package element 2 of FIG. 1 except the photodetector is removed. This allows a user to attach their preferred photodetector on the topside of a laminate substrate 22. The package arrangement 20 includes the laminate substrate 22, ADC plastic molded dies 26, and the solder balls 30 to couple to a PC board, which is similarly arranged as package arrangement 2.

The package arrangement 22 can also be applied in other electronic systems such as medical electronics, digital cameras, IR imagers, laboratory instruments, photodiodes, or the like.

FIG. 3 shows a package arrangement 40 having no laminate substrate. A multiple bump ADC dies flip chip 46 is mounted directly on the underside of a photodetector die 44. The bottom side of the photo detector die 44 is metal patterned to interconnect the ADC dies 46 to the photo detector die 44. Vias 42 are used for coupling the photodiode to it's bottom side. The photodetector die 44 can sit directly on a system PC board using solder balls 48. The package arrangement 40 can also be applied in other electronic systems such as medical electronics, digital cameras, IR imagers, laboratory instruments, photodiodes, or the like.

FIG. 4 shows a package arrangement 66 integrating a photodetector 82 and an analog to digital (ADC) converter dies 76 of a CT scanner. The package arrangement 66 includes a photodetector 82 having solder balls 70 for coupling on a laminate substrate 72 with multiple bumped flip chip ADC dies 76. The photodetector 82 includes photodiode junctions 80 on the top scintillator side and photodetector dies 68. Vias 78 are used for coupling the photodiode junctions 80 to solder balls 70.

The ADC dies 76 is on the front side of the laminate substrate 72. On the other side, solder balls 74 are provided so as to allow a PC board to be coupled to the package arrangement 66. In other embodiments, ceramic interposers can be provided in place of the laminate substrate 72. Also, multiple ADC dies can be provided for one BGA package. The package arrangement 66 can also be applied in other electronic systems such as medical electronics, digital cameras, IR imagers, laboratory instruments, photodiodes, or the like.

Although the present invention has been shown and described with respect to several preferred embodiments thereof, various changes, omissions and additions to the form and detail thereof, may be made therein, without departing from the spirit and scope of the invention.

What is claimed is:

1. An integrated package arrangement for an electronic system comprising:
a photodetector module for incorporating a photodetector for use by said electronic system, and
an analog to digital converter (ADC) module being coupled to said photodetector module, said ADC module comprising a plurality of ADC dies for use by an ADC of said electronic system.

2. The integrated package arrangement of claim 1, wherein said photodetector comprises a plurality of photodiode junctions on the top side of said package arrangement.

3. The integrated package arrangement of claim 1, wherein said ADC module is coupled to said photodetector module using a laminate substrate.

4. The integrated package arrangement of claim 1, wherein said ADC module is directly positioned on said photodetector module.

5. The integrated package arrangement of claim 3, wherein said photodetector module is coupled to said laminate substrate using a plurality of solder balls.

6. The integrated package arrangement of claim 5, wherein said ADC module is coupled to the bottom side of said laminate substrate.

7. The integrated package arrangement of claim 5, wherein said ADC module is coupled to the top side of said laminate substrate.

8. The integrated package arrangement of claim 4, wherein said ADC dies comprise multiple bump flip chip ADC dies.

9. The integrated package arrangement of claim 6, wherein said ADC dies comprise plastic molded ADC dies.

10. The integrated package arrangement of claim 1, wherein said photodetector module uses an underfill so as to allow said photodetector module to have an overhang spacing of at least 160 μm.

11. A method of integrating a photodetector and an analog digital converter (ADC) of an electronic system comprising:
providing a photodetector module for incorporating said photodetector for use by said electronic system, and
coupling an ADC module to said photodetector module, said ADC module comprising a plurality of ADC dies for use by said ADC.

12. The method of claim 11, wherein said photodetector comprises a plurality of photodiode junctions on the top side of said package arrangement.

13. The method of claim 11, wherein said ADC module is coupled to said photodetector module using a laminate substrate.

14. The method of claim 11, wherein said ADC module is directly positioned on said photodetector module.

15. The method of claim 13, wherein said photodetector module is coupled to said laminate substrate using a plurality of solder balls.

16. The method of claim 15, wherein said ADC module is coupled to the bottom side of said laminate substrate.

17. The method of claim 15, wherein said ADC module is coupled to the top side of said laminate substrate.

18. The method of claim 14, wherein said ADC dies comprise multiple bump flip chip ADC dies.

19. The method of claim 16, wherein said ADC dies comprise plastic molded ADC dies.

20. The method of claim 11, wherein said photodetector module uses an underfill so as to allow said photodetector module to have an overhang spacing of at least 160 μm.

21. A method of forming an integrated package arrangement for an electronic system comprising:
forming a photodetector module for incorporating a photodetector for use by said electronic system, and
forming an analog to digital converter (ADC) module being coupled to said photodetector module, ADC module comprising a plurality of ADC dies for use by an ADC of said electronic system.

22. The method of claim 21, wherein said photodetector comprises a plurality of photodiode junctions on the top side of said package arrangement.

23. The method of claim 21, wherein said ADC module is coupled to said photodetector module using a laminate substrate.

24. The method of claim 21, wherein said ADC module is directly positioned on said photodetector module.

25. The method of claim 23, wherein said photodetector module is coupled to said laminate substrate using a plurality of solder balls.

26. The method of claim 25, wherein said ADC module is coupled to the bottom side of said laminate substrate.

27. The method of claim 25, wherein said ADC module is coupled to the top side of said laminate substrate.

28. The method of claim 24, wherein said ADC dies comprise multiple bump flip chip ADC dies.

29. The method of claim 26, wherein said ADC dies comprise plastic molded ADC dies.

30. The method of claim 19, wherein said photodetector module uses an underfill so as to allow said photodetector module to have an overhang spacing of at least 160 μm.

31. The integrated package arrangement of claim 1, wherein said ADC module is coupled to said photodetector module using a ceramic interposer.

32. The method of claim 11, wherein said ADC module is coupled to said photodetector module using a laminate substrate.

33. The method of claim 21, wherein said ADC module is coupled to said photodetector module using a laminate substrate.
